(19) United States
(12) Patent Application Publication
(10) Pub. No.: US 2017/0282527 A1
(43) Pub. Date: Oct. 5, 2017

(54) VACUUM LAMINATING APPARATUS AND METHOD FOR MANUFACTURING SEMICONDUCTOR APPARATUS

(71) Applicant: SHIN-ETSU CHEMICAL CO., LTD., Tokyo (JP)

(72) Inventors: Hideki AKIBA, Annaka (JP); Tomoaki NAKAMURA, Annaka (JP); Toshio SHIOBARA, Annaka (JP)

(73) Assignee: SHIN-ETSU CHEMICAL CO., LTD., Tokyo (JP)

(21) Appl. No.: 15/626,803

(22) Filed: Jun. 19, 2017

Related U.S. Application Data
(62) Division of application No. 14/612,894, filed on Feb. 3, 2015.

(30) Foreign Application Priority Data
Feb. 18, 2014 (JP) 2014-28919
Feb. 18, 2014 (JP) 2014-28921

(51) Int. Cl. B32B 37/10; H01L 21/56; B32B 37/00; H01L 21/78; H01L 23/00; B32B 37/24; H01L 21/67

(52) U.S. Cl. CPC B32B 37/1018; H01L 21/67126; H01L 21/565; B32B 37/0046; B32B 2398/10; B32B 2457/14; H01L 24/97; H01L 2224/16225; B32B 37/0015; B32B 37/24; B32B 2363/00; H01L 2924/12042; H01L 21/78; H01L 21/561; H01L 2924/181; H01L 2924/00

(57) ABSTRACT

Manufacturing a semiconductor apparatus includes preparing a support-base attached encapsulant including a thermosetting resin layer stacked as an encapsulant on a support base, coating a semiconductor-device mounting surface of a substrate on which semiconductor devices are mounted, or a semiconductor-device forming surface of a wafer on which semiconductor devices are formed with the thermosetting resin layer of the support-base attached encapsulant, heating and curing the thermosetting resin layer to collectively encapsulate the semiconductor-device mounting surface of the substrate or the semiconductor-device forming surface of the wafer, and cutting the encapsulated substrate or wafer by dicing. Coating includes surrounding a side face of the support-base attached encapsulant by a frame mechanism, holding the substrate or the wafer with the substrate or the wafer facing and spaced apart from the thermosetting resin layer of the support-base attached encapsulant, and vacuum laminating the support-base attached encapsulant together with the substrate or the wafer.

### BACKGROUND OF THE INVENTION

### Field of the Invention

The present invention relates to a method for manufacturing a semiconductor apparatus with a support-base attached encapsulant and a vacuum laminating apparatus for use in the manufacture.

### Description of the Related Art

In recent years, semiconductor devices have been more integrated and thinned as electronic devices are reduced in size and weight and improved in performance. There has been a transition of semiconductor devices to area mounting semiconductor devices, represented by ball grid arrays (BGA). These semiconductor devices tend to be manufactured by collectively molding a thin substrate with a large area from the viewpoint of productivity. The problem of the warp of substrates after molding however has been revealed.

The semiconductor mounting technique has also been shifted from pin insertion to surface mounting; currently bare chip mounting is becoming more prevalent. Flip chip mounting is one of the bare chip mounting techniques. In flip chip mounting, electrode terminals called bumps are formed on a semiconductor device. This can be directly mounted on a motherboard, but is in many cases fixed on a printed circuit board (such as an interposer) to form a package and mounted on a motherboard via external connection terminals (also referred to as outer balls or outer bumps) provided on the package. The bumps on a silicon chip to be connected with the interposer are called inner bumps, which are electrically connected with a large number of fine interfaces (referred to as pads) on the interposer.

Since junctions between the inner bumps and the pads are very small and thus mechanically weak, the junctions are encapsulated and reinforced with resin. The conventional procedure most often used for encapsulating a semiconductor apparatus after flip chip bonding involves previous fusion bonding between the inner bumps and the pads, underfilling (also referred to as capillary flow) by injecting a liquid reinforcement in a gap between the semiconductor device and the interposer, and compression molding under heating with a liquid epoxy resin or an epoxy molding compound, etc., to encapsulate (overmold) silicon chips.

In this procedure, however, the underfilling needs to be performed separately from the encapsulation of chips, resulting in poor productivity. In addition, the procedure has problems: voids are produced in the reinforcement (underfill); the underfilling requires much effort; when different resins are used for the underfilling and the encapsulation of chips, a stress is applied to a resin interface, causing reduction in reliability.

A known method to solve these problems is to perform the underfilling and encapsulation of chips at the same time by transfer molding or compression molding (See Patent Documents 1 and 2).

### CITATION LIST

### Patent Literature

[Patent Document 1] Japanese Patent Application Publication No. 2012-74613

[Patent Document 2] Japanese Patent Application Publication No. 2011-132268

### SUMMARY OF THE INVENTION

The method using transfer molding or compression molding however may produce voids in a resin layer to be molded. This method can be considered to be performed under a reduced pressure to inhibit the occurrence of voids, but then requires a high precision of a mold in order to ensure a degree of vacuum enough to inhibit the voids, resulting in an increase in cost. In particular, molding of a substrate with a large area needs a higher degree of vacuum, which is very difficult to ensure by the mold precision. Accordingly, the conventional method, when a substrate with a large area is molded, cannot inhibit the voids in the resin layer.

The present invention was accomplished in view of the above problem, and it is an object of the present invention to provide a manufacturing method that can inhibit the occurrence of voids in a resin layer and the warp of a substrate (or a wafer) and manufacture a semiconductor apparatus having a precisely formed resin layer at low cost, even when the substrate (or the wafer) used has a large area.

To achieve this object, the present invention provides a vacuum laminating apparatus for use in manufacturing a semiconductor apparatus, comprising a frame mechanism configured to surround at least a side face of a support-base attached encapsulant including a thermosetting resin layer stacked as an encapsulant on a support base, the frame mechanism including a holding unit configured to hold a substrate on which semiconductor devices are mounted or a wafer on which semiconductor devices are formed with the substrate or the wafer facing and spaced apart from the thermosetting resin layer of the support-base attached encapsulant, the vacuum laminating apparatus being capable of vacuum laminating the support-base attached encapsulant surrounded by the frame mechanism together with the substrate or the wafer.

Such a vacuum laminating apparatus can perform the vacuum lamination under a vacuum enough to inhibit voids, enabling the inhibition of the occurrence of voids in the thermosetting resin layer at low cost. The occurrence of voids in underfill, particularly when a substrate or wafer with a large area is used, can be inhibited, which is conventionally difficult to inhibit. In addition, the frame mechanism can prevent a lower portion of the outer circumference of the thermosetting resin layer from being formed into a laterally extending shape, thereby enabling the thermosetting resin layer to be precisely formed. In addition, the support base can inhibit the warp of the substrate or wafer.

The frame mechanism preferably includes a resin discharging unit configured to discharge an excess of the thermosetting resin layer to the exterior.

Such an apparatus can reliably form the thermosetting resin layer with high precision while inhibiting the occurrence of voids therein and readily manage the amount of the thermosetting resin layer stacked on the support base.

The holding unit of the frame mechanism is preferably configured to hold the substrate or the wafer from above with a semiconductor-device mounting surface or a semiconductor-device forming surface facing downward, and has a fastener to be engaged with a peripheral portion of the substrate or the wafer.

Such an apparatus can vacuum laminate the support-base attached encapsulant with the thermosetting resin layer placed so as to face upward, thereby enabling a part of the thermosetting resin layer to be prevented from falling out of the support base.

The frame mechanism preferably includes a bottom on which the support-base attached encapsulant is to be placed and a side part movable upward and downward in sliding contact with the bottom, and the bottom and the side part are preferably made of heat-resistant resin.

Such an apparatus can narrow a gap at the sliding contact by the heat-resistant resin as possible and inhibit a part of the thermosetting resin layer from leaking through the gap, thereby enabling the thermosetting′ resin layer to be more reliably formed with high precision.

Furthermore the present invention provides a method for manufacturing a semiconductor apparatus, comprising: a preparation step of preparing a support-base attached encapsulant including a thermosetting resin layer stacked as an encapsulant on a support base; a coating step of coating a semiconductor-device mounting surface of a substrate on which semiconductor devices are mounted, or a semiconductor-device forming surface of a wafer on which semiconductor devices are formed with the thermosetting resin layer of the support-base attached encapsulant; an encapsulating step of heating and curing the thermosetting resin layer to collectively encapsulate the semiconductor-device mounting surface of the substrate or the semiconductor-device forming surface of the wafer; a cutting step of cutting the encapsulated substrate or wafer by dicing; wherein the coating step includes surrounding at least a side face of the support-base attached encapsulant by a frame mechanism, holding the substrate or the wafer with the substrate or the wafer facing and spaced apart from the thermosetting resin layer of the support-base attached encapsulant, and vacuum laminating the support-base attached encapsulant surrounded by the frame mechanism together with the substrate or the wafer.

Such a manufacturing method can inhibit the occurrence of voids in the thermosetting resin layer at low cost by performing the vacuum lamination under a vacuum enough to inhibit the voids. The occurrence of voids in underfill, particularly when a substrate or wafer with a large area is used, can be inhibited, which is conventionally difficult to inhibit. In addition, the frame mechanism can prevent a lower portion of the outer circumference of the thermosetting resin layer from being formed into a laterally extending shape, thereby enabling the thermosetting resin layer to be precisely formed.

The preparation step preferably includes stacking the thermosetting resin layer as an encapsulant on the support base in excess of an amount necessary for manufacturing the semiconductor apparatus, and the coating step is preferably performed while discharging an excess of the thermosetting resin layer to an exterior.

In this manner, the thermosetting resin layer can reliably be formed with high precision while the occurrence of voids therein is inhibited and the amount of the thermosetting resin layer stacked on the support base can readily be managed.

The coating step preferably includes engaging a fastener with a peripheral portion of the substrate or the wafer to hold the substrate or the wafer from above with the semiconductor-device mounting surface or the semiconductor-device forming surface facing downward.

In this manner, the support-base attached encapsulant can be vacuum laminated with the thermosetting resin layer placed so as to face upward; thereby a part of the thermosetting resin layer can be prevented from falling out of the support base.

The vacuum lamination in the coating step is preferably performed under a reduced pressure of 10 Pa to 1 kPa.

In this manner, the occurrence of voids in the thermosetting resin layer can be effectively inhibited by the vacuum lamination under the above reduced pressure. In addition, since an expensive mold is not needed to ensure the above reduced pressure, the method can be performed at low cost.

In the method, a substrate having an area of 200 mm×200 mm or more can be used as the substrate on which semiconductor devices are mounted, and a wafer having an area of a diameter of 200 mm or more can be used as the wafer on which semiconductor devices are formed.

The inventive manufacturing method can exert the above effects even when such a substrate or wafer with a large area is used.

Moreover, a vacuum laminating apparatus capable of heating the substrate or the wafer under vacuum can be used to perform the vacuum lamination in the coating step and subsequently the encapsulating step.

In this manner, the encapsulating step can readily be performed in a short time.

When a semiconductor apparatus is manufactured with the inventive vacuum lamination apparatus having the frame mechanism, the occurrence of voids in the thermosetting resin layer can be inhibited at low cost. The occurrence of voids in underfill, particularly when a substrate or wafer with a large area is used, can be inhibited, which is conventionally difficult to inhibit. In addition, the frame mechanism can prevent a lower portion of the outer circumference of the thermosetting resin layer from being formed into a laterally extending shape, the so-called sag shape; thereby the accuracy of the thermosetting resin layer can be improved. In addition, since a semiconductor-device mounting surface or a semiconductor-device forming surface is encapsulated with a support-base attached encapsulant including the thermosetting resin layer stacked on a support base, the warp of the substrate or the wafer can be inhibited.

### BRIEF DESCRIPTION OF THE DRAWINGS

FIG. 1 is a schematic cross-sectional view of an example of the inventive vacuum laminating apparatus;

FIG. 2 is a schematic cross-sectional view of an exemplary frame mechanism of the inventive vacuum laminating apparatus;

FIG. 3 is a schematic cross-sectional view of an exemplary frame mechanism of the inventive vacuum laminating apparatus;

FIG. 4 is a flow diagram of an example of the inventive method for manufacturing a semiconductor apparatus;

FIG. 5 is a flow diagram of an example of the coating step and the encapsulating step in the inventive method for manufacturing a semiconductor apparatus;

FIG. 6 is a schematic diagram showing a condition where the frame mechanism of the inventive vacuum laminating apparatus prevents a resin sag; and

FIG. 7 is a schematic diagram showing a condition where a conventional vacuum laminating apparatus produces a resin sag.

### DETAILED DESCRIPTION OF THE PREFERRED EMBODIMENTS

The inventive method for manufacturing a semiconductor apparatus will be described in detail, but the present invention is not limited thereto.

As described previously, the conventional method of encapsulating semiconductor devices with a thermosetting resin layer by using transfer molding or compression molding increases cost and is difficult to inhibit the occurrence of voids in the thermosetting resin layer, particularly when a substrate (or wafer) with a large area is used.

The present inventors diligently conducted study on the above problem and consequently found the following, thereby bringing the present invention to completion. Specifically, vacuum lamination under a prescribed reduced pressure is used to coat with a support-base attached encapsulant the semiconductor-device mounting surface (hereinafter, simply referred to as the device mounting surface) of a substrate on which semiconductor devices are mounted (hereinafter, simply referred to as a device mounting substrate), or the semiconductor-device forming surface (hereinafter, simply referred to as the device forming surface) of a wafer on which semiconductor devices are formed (hereinafter, simply referred to as a device forming wafer). The vacuum laminating apparatus used in the coating is provided with a frame mechanism. This apparatus is configured such that the frame mechanism surrounds at least a side face of the support-base attached encapsulant and holds the device mounting substrate or the device forming wafer with the substrate or the wafer facing and spaced apart from a thermosetting resin layer of the support-base attached encapsulant. The inventive vacuum laminating apparatus of this type can inhibit the occurrence of voids in the thermosetting resin layer and ensure precise formation of the thermosetting resin layer at low cost. In addition, the vacuum lamination under a reduced pressure of 10 Pa to 1 kPa enables the voids to be effectively inhibited,

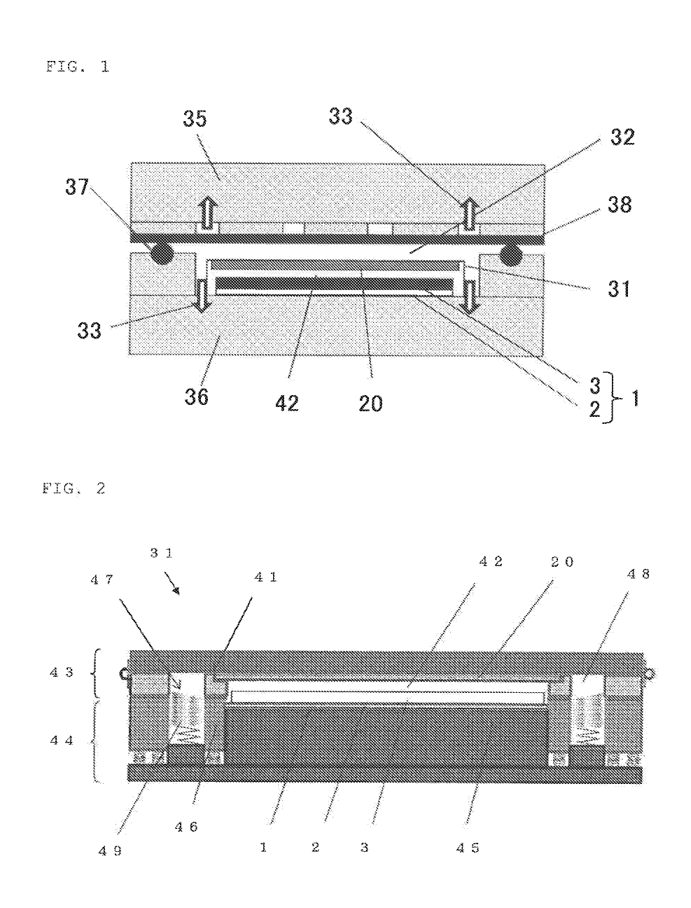

The inventive vacuum laminating apparatus will now be described with reference to FIGS. 1 and 2.

As shown in FIG. 2, a support-base attached encapsulant, which will be described below in detail, is composed of a thermosetting resin layer 3 stacked as an encapsulant on a support base 2. This embodiment describes an example of coating a device mounting substrate with the support-base attached encapsulant, but a device forming wafer can be coated in the same manner.

As shown in FIG. 1, the vacuum laminating apparatus 30 includes a frame mechanism 31, a vacuum chamber 32, a vacuum unit 33, and a pressing unit 34.

The frame mechanism 31 is configured to surround at least a side face of a support-base attached encapsulant 1 and, as shown in FIG. 2, has a holding unit 41 configured to hold a device mounting substrate 20 while the substrate faces the thermosetting resin layer 3 of the support-base attached encapsulant 1 and is spaced apart therefrom to define a space 42. The frame mechanism 31 holding the device mounting substrate 20 and the support-base attached encapsulant 1 is placed in the interior of the vacuum chamber 32.

The vacuum chamber 32 can be defined, for example, by disposing an O-ring 37 at the lower end of a flange located at the periphery of an upper plate 35 and bringing the upper plate 35 into close contact with a lower plate 36. Both the upper plate 35 and the lower plate 36 may have built-in heaters. These heaters enable the thermosetting resin layer 3 to be heated and cured during vacuum lamination, that is, vacuum lamination accompanied by the encapsulation of a device mounting surface or a device forming surface.

The vacuum unit 33 has a vacuum pump connecting with the vacuum chamber 32 and produces a vacuum at a prescribed reduced pressure, such as for example 1 kPa or less, in the vacuum chamber 32,

The pressing unit 34 is configured to press the frame mechanism 31 placed in the interior of the vacuum chamber 32 at a prescribed pressing force. This enables the support-base attached encapsulant. 1 surrounded by the frame mechanism 31 to be vacuum laminated together with the device mounting substrate 20. The pressing unit 34 can be composed of, for example, a diaphragm rubber 38 disposed between the upper plate 35 and the lower plate 36 and a compressor (not shown) for supplying a compressed air between the upper plate 35 and the diaphragm rubber 38. The compressed air supplied to between the upper plate 35 and the diaphragm rubber 38 inflates the diaphragm rubber 38 to squeeze the device mounting substrate 20 and the support-base attached encapsulant 1 between the diaphragm rubber 38 and the lower plate 36 through the frame mechanism 31; thus vacuum lamination is performed. In this case, the pressing force by the pressing unit 34 is adjusted by the amount of the compressed air to be supplied.

The vacuum pump of the vacuum unit 33 may be configured to connect with the vacuum chamber 32 via both sides of the upper plate 35 and the lower plate 36. This configuration enables vacuums to be drawn independently of one another in two spaces into which the vacuum chamber 32 is divided one above the other by the diaphragm rubber 38.

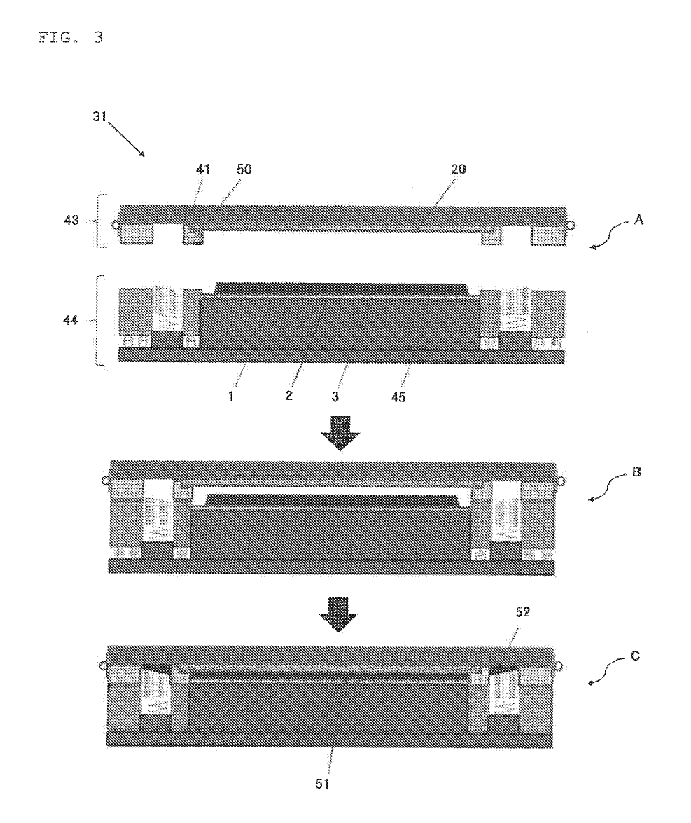

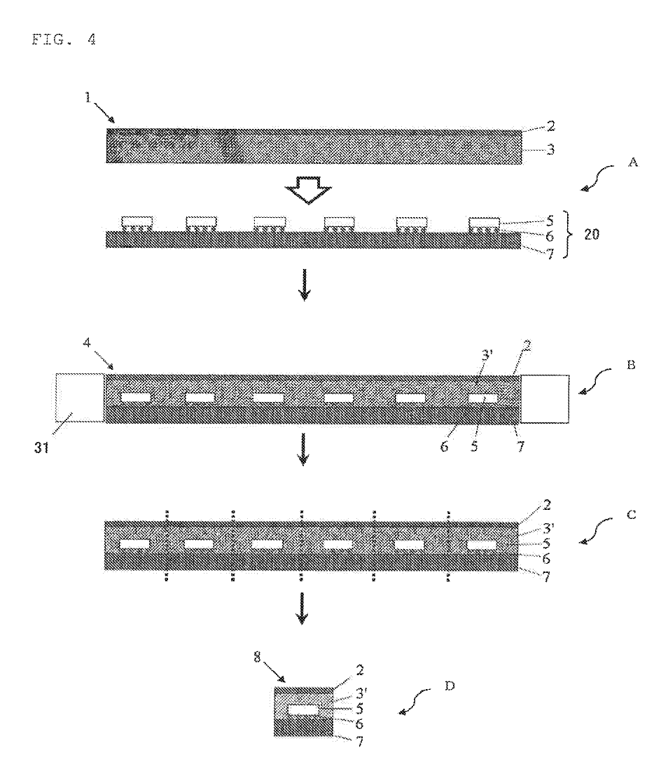

A preferable aspect of the frame mechanism 31 will now be described in detail with reference to FIGS. 2 and 3.

The frame mechanism 31 shown in FIGS. 2 and 3 is configured to be dividable into an upper part 43 and a lower part 44. The lower part 44 has a bottom 45 and a side part 46. As shown in FIG. 3, when the upper part 43 is detached from the lower part 44, the support-base attached encapsulant 1 can readily be placed on the bottom 45.

The side part 46 can be configured so as to be movable upward and downward in sliding contact with the bottom 45. In this case, the bottom 45 or the side part 46 is preferably partially made of heat-resistant resin, such as fluoro-resin. Such a frame mechanism can narrow a gap formed for sliding contact between the bottom. 45 and the side part 46 by the heat-resistant resin as possible. The leakage of resin through the gap can consequently be inhibited and the thermosetting resin layer 3 can reliably be formed with high precision.

The frame mechanism 31 has a resin discharging unit 47 configured to discharge an excess of the thermosetting resin layer 3, that is, a resin in excess of an amount necessary for manufacturing a semiconductor apparatus, to the exterior. The resin discharging unit 47 has a store chamber 48 for temporally storing the resin discharged through a hole (not shown) connected with the space 42 defined between the support-base attached encapsulant 1 and the device mounting substrate 20 and a pushing means 49 to prevent the resin from being excessively discharged. The resin discharging unit 47 enables the thermosetting resin layer 3 to be reliably precisely formed with a desired thickness and suppressed voids. In an example shown in FIGS. 2 and 3, the pushing means 49 is configured by using a spring.

The vacuum laminating apparatus 30 including the resin discharging unit 47 can manufacture a semiconductor apparatus with a desired thickness by adjusting the pressing force by the pressing unit 34,

In manufacture of a semiconductor apparatus by using a substrate on which plural semiconductor devices are mounted or a wafer on which plural semiconductor devices are formed, if some faulty semiconductor devices are included therein, then the encapsulation is performed after the faulty devices are removed from the substrate or the wafer. In this case, the amount of the thermosetting resin layer 3 necessary for manufacturing the semiconductor apparatus increases by the volume of the removed faulty devices. The vacuum laminating apparatus including the resin discharging unit 47 can perform vacuum lamination while discharging an excess of the thermosetting resin layer 3 to the exterior by previously stacking the thermosetting resin layer 3 on the support base 2 in excess of the necessary amount, thereby making the management of the amount of resin extremely easy.

The vacuum lamination is preferably performed with the thermosetting resin layer 3 facing upward and the device mounting surface of the device mounting substrate 20 facing downward, in order to prevent a part of the thermosetting resin layer 3 of the support-base attached encapsulant 1 from falling out of the support base 2. As shown in FIG. 3, the holding unit 41 of the frame mechanism 31 accordingly has a fastener 50 to be engaged with a peripheral portion of the device mounting substrate 20. This holding unit 41 can readily hold the device mounting substrate 20 from above with the device mounting surface facing downward.

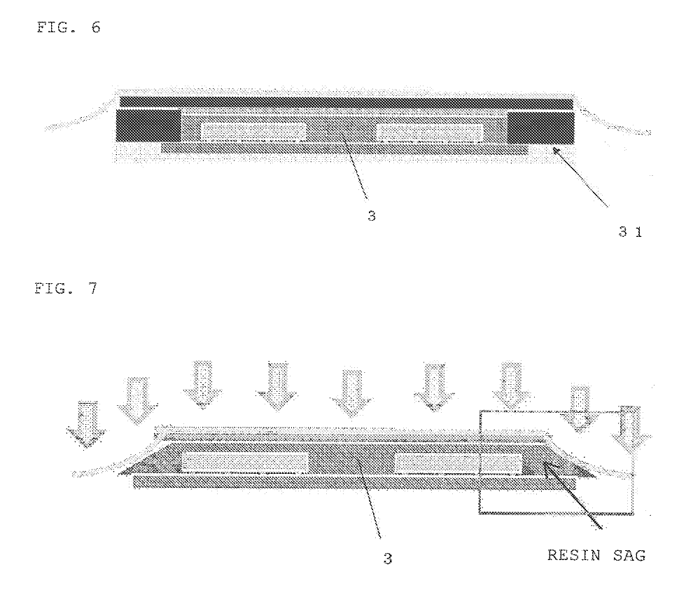

The inventive vacuum laminating apparatus of this type can perform vacuum lamination under a vacuum enough to inhibit voids, such as for example 1 kPa or less, thereby enabling the inhibition of the occurrence of voids in the thermosetting resin layer at low cost. The occurrence of voids in underfill, particularly when a substrate or wafer with a large area is used, can be inhibited. In addition, as shown in FIG. 6, the frame mechanism 31 can prevent the thermosetting resin layer 3 from being formed into a sag shape, thereby enabling improvement in accuracy of the thermosetting resin layer 3.

In contrast, as shown in FIG. 7, a conventional vacuum laminating apparatus, which does not have the frame mechanism 31 unlike the present invention, molds a lower portion of the outer circumference of the thermosetting resin layer 3 into a laterally extending shape, the so-called sag shape.

The frame mechanism of the inventive vacuum laminating apparatus need only be capable of surrounding at least a side face of the support-base attached encapsulant to prevent the resin sag, but is not limited to the above exemplified configuration. More specifically, the frame mechanism is not limited to being composed of plural members such as the upper part, the lower part, the side part, the bottom, but may be formed integrally as a whole.

Next, the inventive method for manufacturing a semiconductor apparatus will be described.

FIG. 4 shows an example of the inventive method for manufacturing a semiconductor apparatus using, for example, a device mounting substrate of flip chip connection. The inventive method for manufacturing a semiconductor apparatus includes a preparation step (See FIG. 4 at ‘A’) for a support-base attached encapsulant, a coating step (See FIG. 4 at ‘A’ and ‘B’) of and an encapsulating step (See FIG. 4 at ‘B’ and ‘C’) of a device mounting surface or a device forming surface, cutting step (See FIG. 4 at ‘C’ and ‘D’) of cutting an encapsulated substrate or wafer. The present invention is characterized by the coating step being performed by vacuum lamination with the frame mechanism 31.

### <Preparation Step>

First, a support-base attached encapsulant 1 is prepared as shown in FIG. 4. The support-base attached encapsulant 1 is made by stacking a thermosetting resin layer 3 on a surface of a support base 2. In addition, a device mounting substrate 20 or a device forming wafer, which is a subject to be encapsulated with the support-base attached encapsulant 1, may also be prepared in this step.

Examples of the method of stacking the thermosetting resin layer 3 includes a method of stacking an uncured thermosetting resin in a sheet state or a film state on a surface of the support base 2 and forming the resin layer by vacuum laminating, high-temperature vacuum pressing, or a heating roller, a method of applying a thermosetting resin, such as liquid epoxy resin or silicone resin, by printing or dispensing, etc., under a reduced pressure or a vacuum and then heating the resin, and a method of press forming an uncured thermosetting resin.

A thin resin layer may be formed on a surface of the support base 2 of the support-base attached encapsulant 1 on the opposite side of the thermosetting resin layer 3. Examples of the method of forming the thin resin layer include a method of forming the resin layer on the support base 2 by printing, spraying, coating, press forming, or film thermal compression bonding and then curing the layer by heat or light; the press forming and the film thermal compression bonding have been used for an epoxy curable resin or a silicone curable resin.

The formed thin resin layer allows a semiconductor apparatus encapsulated with the support-base attached encapsulant 1 to have the same appearance and laser marking property as in a conventional semiconductor apparatus encapsulated merely with an epoxy resin.

### [Support Base]

The support base 2 is effective in inhibiting a shrinkage stress produced when the thermosetting resin layer 3 is cured, as described later and important to reduce the warp of an encapsulated substrate or wafer and to reinforce a substrate in which semiconductor devices are arranged and bonded. Accordingly, the support base 2 is preferably hard and robust, but not limited in particular; an inorganic substrate, a metal substrate, or an organic resin substrate may be used as the support base 2 according to a subject to be encapsulated, a device mounting substrate or a device forming substrate. In particular, when an organic resin substrate is used, the organic resin substrate may contain a fibrous base.

Typical examples of the inorganic substrate include a ceramics substrate, a glass substrate, and a silicon wafer. Typical examples of the metal substrate include a copper or aluminum substrate whose surface has been subjected to an insulation treatment. Examples of the organic resin substrate include a resin-impregnated fibrous base in which a thermosetting resin or a filler, etc., has been impregnated into a fibrous base, and a resin-impregnated fibrous base in which a thermosetting resin has been semi-cured or cured, and a resin substrate in which a thermosetting resin has been formed into a substrate shape. Typical examples of the substrate include a BT (bismaleimide triazine) resin substrate, a glass epoxy substrate, and a FRP (fiber reinforced plastic) substrate.

Exemplary materials that can be used for the fibrous base contained in the organic resin substrate include an inorganic fiber such as carbon fiber, glass fiber, quartz glass fiber, or metal fiber; an organic fiber such as aromatic polyamide fiber, polyimide fiber, or polyamideimide fiber; silicon carbide fiber; titanium carbide fiber; boron fiber; alumina fiber; and any other materials depending on the product properties. The most preferred fibrous base may be exemplified by glass fiber, quartz fiber, or carbon fiber. Above all, glass fiber or quartz glass fiber having high insulation property is preferred as the fibrous base.

The thermosetting resin used for the organic resin substrate is not particularly limited, but may be a BT resin or an epoxy resin; an epoxy resin, a silicone resin, a hybrid resin comprising an epoxy resin and a silicone resin, and a cyanate ester resin, which are conventionally used for encapsulating semiconductor devices and described below, may also be given as an example.

When the support-base attached encapsulant is manufactured with a resin-impregnated fibrous base using a thermosetting epoxy resin as the thermosetting resin to be impregnated into the fibrous base, or the resin-impregnated fibrous base after the epoxy resin is semi-cured, the thermosetting resin used for forming the thermosetting resin layer on a surface of the support base is also preferably an epoxy resin. When the thermosetting resin impregnated into the support base and the thermosetting resin of the thermosetting resin layer are identical, the resins can be simultaneously cured when a device mounting surface or a device forming wafer is collectively encapsulated, whereby more firm encapsulating function can be preferably accomplished.

When a silicone resin, a hybrid resin comprising an epoxy resin and a silicone resin, or a cyanate ester resin is used as the thermosetting resin to be impregnated into the fibrous base, the thermosetting resin impregnated into the support base and the thermosetting resin of the thermosetting resin layer are also preferably identical.

In all the cases of using an inorganic substrate, a metal substrate, or an organic resin substrate, the thickness of the support base is preferably in the range from 20 μm to 1 mm, more preferably from 30 μm to 500 μm. The reason why such a thickness is preferable is that when the thickness is 20 μm or more, the substrate can be inhibited from becoming easy to deform due to being too thin; when the thickness is 1 mm or less, the apparatus itself can be inhibited from becoming thick.

### [Thermosetting Resin Layer]

The thermosetting resin layer 3 functions as an encapsulant when semiconductor devices are encapsulated, as described later. When semiconductor devices mounted on the substrate through flip chip connection are encapsulated, the thermosetting resin layer 3 also functions as a resin layer for underfill.

The thickness of the thermosetting resin layer 3 is preferably in the range between 20 μm and 2,000 μm. When the thickness is 20 μm or more, a device mounting surface or a device forming surface is sufficiently encapsulated and the occurrence of a failure in filling due to being too thin can preferably be inhibited; when the thickness is 2000 μm or less, an encapsulated semiconductor apparatus can preferably be inhibited from becoming too thick.

The resin used for the thermosetting resin layer 3 is preferably, but not limited to, a liquid epoxy resin, a solid epoxy resin, a silicone resin, a hybrid resin of an epoxy resin and a silicone resin, or a cyanate ester resin, each of which is generally used for encapsulating semiconductor devices. In particular, the thermosetting resin layer 3 preferably contains at least one of an epoxy resin, a silicone resin, an epoxy-silicone hybrid resin, and a cyanate ester resin, each of which solidifies at temperatures lower than 50° C. and melts at temperatures ranging from 50° C. to 150° C.

### [Device Mounting Substrate or Device Forming Wafer]

As shown in FIG. 4, examples of the device mounting substrate include a substrate 7 on which semiconductor devices 5 are mounted via bumps 6 through flip chip connection. The substrate 7 preferably has a gap size (a width between the substrate and the semiconductor chip) of about 10 to 200 μm. The device mounting substrate may also be an inorganic substrate, a metal substrate, or an organic substrate on which semiconductor devices are mounted through an adhesive. The device forming wafer may be a wafer on which semiconductor devices are formed. The device mounting substrate may include a semiconductor device array on which semiconductor devices are mounted and arranged.

The device mounting substrate or the device forming wafer may have an area equal to or more than 200 mm×200 mm or equal to or more than a diameter of 200 mm, for example, an area of 300 mm×300 mm or a diameter of 300 mm.

### <Coating Step>

In the coating step, the device mounting surface of the device mounting substrate 20 (or the device forming surface of the device forming wafer) is coated with the thermosetting resin layer 3 of the support-base attached encapsulant 1 (See FIG. 4 at ‘A’ and ‘13’). When the substrate of fillip chip connection is coated, the underfilling is performed at the same time in the coating step.

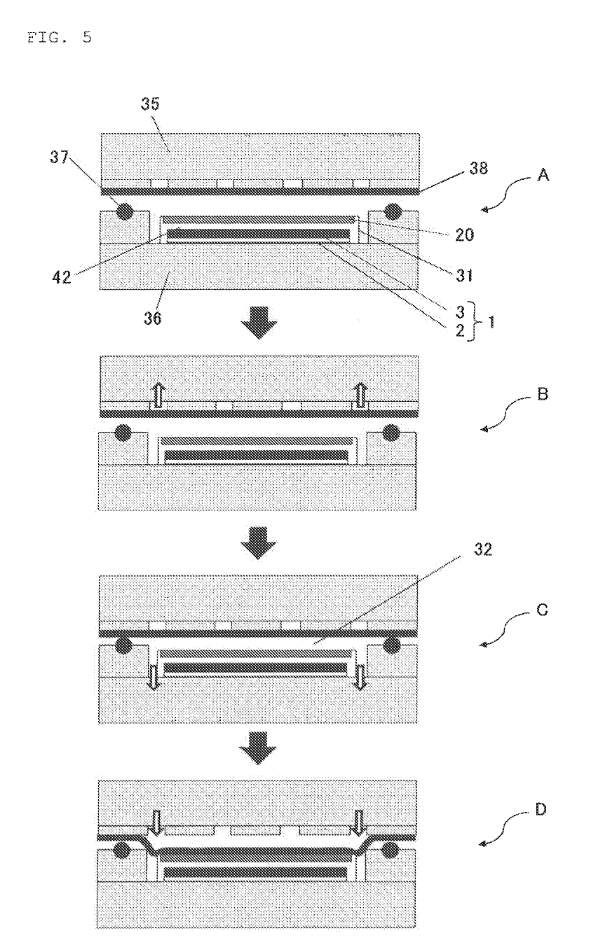

In the present invention, the coating step uses the inventive vacuum lamination apparatus, as described above. Specifically, as shown in FIG. 5, at least a side face of the support-base attached encapsulant 1 is surrounded by the frame mechanism 31, and the device mounting substrate 20 or the device forming wafer is held such that the substrate or the wafer faces the thermosetting resin layer 3 of the support-base attached encapsulant 1 and is spaced apart therefrom to define a space 2. As described previously, the substrate 20 (or the wafer) is preferably held from above while the device mounting surface (or the device forming surface) faces downward and a fastener is engaged with a peripheral portion of the substrate 20 (or the wafer), in order to prevent a part of the thermosetting resin layer 3 from falling out of the support base 2.

The support-base attached encapsulant 1 surrounded by the frame mechanism 31 is vacuum laminated together with the substrate 20 or the wafer.

In the preparation step, the thermosetting resin layer 3 is preferably stacked on the support base 2 in excess of an amount necessary for manufacturing the semiconductor apparatus and the coating step is preferably performed while discharging an excess of the thermosetting resin layer 3 to the exterior. In this manner, the need for complicated adjustment of the amount of the thermosetting resin layer 3 stacked on the support base 2 is eliminated; thereby the semiconductor apparatus can be readily manufactured and the occurrence of voids in the thermosetting resin layer 3 can be reliably inhibited. The amount necessary for manufacturing the semiconductor apparatus may be, for example, the amount required for obtaining a semiconductor apparatus having a desired thickness when a substrate or a wafer having no semiconductor device is encapsulated with the support-base attached encapsulant 1. In this manner, the amount of resin can readily be determined regardless of the number of faulty semiconductor devices.

The vacuum lamination in the coating step is preferably performed under a reduced pressure of 10 Pa to 1 kPa.

When the vacuum lamination is performed under a reduced pressure of 1 kPa or less, the occurrence of voids in the thermosetting resin layer 3 can reliably be inhibited; when the vacuum lamination is performed under a reduced pressure of 10 Pa or more, there is no need for high cost of vacuum equipment.

### <Encapsulating Step>

The encapsulating step is to collectively encapsulate the device mounting surface or the device forming surface by heating and curing the thermosetting resin layer 3 after the above coating step (See FIG. 4 at ‘B’).

As shown in FIG. 4 at ‘B’, the encapsulated substrate 4 is obtained by simultaneously performing the underfilling and the encapsulating of the device mounting surface of the substrate 7, on which semiconductor devices 5 are mounted via the bumps 6, with the thermosetting resin layer 3, and then heating and curing the thermosetting resin layer 3 to form an encapsulating resin layer 3′. The substrate 4 is collectively encapsulated with support-base attached encapsulant 1.

The method of performing the coating step and the encapsulating step by vacuum lamination will be described in more detail. The description is given by way of example with reference to FIG. 5, with regard to the case of encapsulating the device mounting substrate 20 of flip chip connection, as shown in FIG. 4, with a support-base attached encapsulant having a thermosetting resin layer made of an uncured thermosetting silicone resin by using the inventive vacuum lamination apparatus 30.

The support-base attached encapsulant 1 is placed on the bottom of the frame mechanism 31 of the vacuum lamination apparatus 30. At least a side face of the support-base attached encapsulant 1 is surrounded by the frame mechanism 31. The device mounting substrate 20 is held with the frame mechanism 31 such that the substrate faces the thermosetting resin layer 3 of the support-base attached encapsulant 1 and is spaced apart therefrom to define the space 42 (See FIG. 5 at ‘A’). Alternatively, the frame mechanism 31 may be placed on the bottom of the vacuum lamination apparatus 30 after the support-base attached encapsulant 1 and the device mounting substrate 20 are held with the frame mechanism 31. It is also possible to place support-base attached encapsulant 1 such that the thermosetting resin layer 3 is positioned above the device mounting surface.

The built-in heaters of the upper and lower plates 35 and 36 are set such that the upper and lower plates 35 and 36 are heated to a prescribed temperature, such as for example 150° C. These heaters enable the device mounting substrate 20 to be heated under vacuum. The pressure of the space surrounded by the upper plate 35 and the diaphragm rubber 38 is reduced from the side of the upper plate 35 to bring the diaphragm rubber 38 into close contact with the upper plate 35 (See FIG. 5 at ‘B’)

The vacuum chamber 32 is then defined by raising the lower plate 36 and the pressure of the vacuum chamber 32 is reduced from the side of the lower plate (See FIG. 5 at ‘C’). Once the pressure of the vacuum chamber 32 is reduced to a prescribed reduced pressure such as for example 1 kPa or less, the valve of a pipe connecting the upper plate 35 and the vacuum pump is closed, and then compressed air is supplied to between the upper plate 35 and the diaphragm rubber 38 (See FIG. 5 at ‘D’). This inflates the diaphragm rubber 38, so the device mounting substrate 20 and the support-base attached encapsulant 1 is squeezed between the diaphragm rubber 38 and the lower plate 36 through the frame mechanism 31; thus vacuum lamination is performed. The device mounting surface can consequently be coated while the occurrence of voids and sag shape in the thermosetting resin layer 3 is effectively inhibited. The underfilling is also performed simultaneously with the coating.

The coating is accompanied by the progress of the curing of the thermosetting resin layer 3; thus the device mounting surface is encapsulated. In other words, after the coating step, the encapsulating step is subsequently performed. A sufficient curing time is roughly 3 to 20 minutes. The shrinkage stress is produced when the thermosetting resin layer 3 is cured. The present invention however uses a support-base attached encapsulant, thereby enabling the inhibition of the warp of a substrate due to the shrinkage stress by the support base 2. After the vacuum lamination is completed, the pressure of the vacuum chamber is increased to a normal pressure, and the lower plate 36 is lowered to take out the encapsulated device mounting substrate.

The above steps enable the acquirement of a warp-free encapsulated device mounting substrate having a void-free and sag-free thermosetting resin layer 3 precisely formed. The device mounting substrate taken out is post-cured typically at 150 to 250° C. for 1 to 8 hours, particularly at 150 to 180° C. for 1 to 4 hours to stabilize electrical and mechanical properties.

In the above embodiment, the coating and encapsulating of a substrate of flip chip connection are described; the inventive method can also be used for a substrate on which semiconductor devices are mounted through an adhesive or a wafer on which semiconductor devices are formed, as described above, to obtain the same effects.

### <Cutting Step>

In the cutting step, the above substrate or wafer after the encapsulating step is cut by dicing (See FIG. 4 at ‘C’ and ‘D’). The substrate after the encapsulating is cut at dotted lines shown in FIG. 4 at ‘C’, for example, with a dicing blade. This step enables an individual semiconductor apparatus 8 to be obtained (See FIG. 4 at ‘D’).

The semiconductor apparatus manufactured in this way is a high quality semiconductor apparatus with high reliability of heat-resistant and wet-resistant properties. In this semiconductor apparatus, semiconductor devices on a substrate or a wafer are encapsulated with void-free thermosetting resin layer and even when a thin substrate or wafer with a large area is used, its warp is small.

### [Epoxy Resin]

The epoxy resin to be used for the thermosetting resin layer of the support-base attached encapsulant, may be for example, but not particularly limited to, a bisphenol type epoxy resin such as a bisphenol A type epoxy resin and a bisphenol F type epoxy resin; a biphenol type epoxy resin such as a 3,3′,5,5′-tetramethyl-4,4′-biphenol type epoxy resin and a 4,4′-biphenol type epoxy resin; an epoxy resin in which an aromatic ring of a phenol novolac type epoxy resin, a cresol novolac type epoxy resin, a bisphenol novolac type epoxy resin, a naphthalenediol type epoxy resin, a trisphenylolmethane type epoxy resin, a tetrakis-phenylolethane type epoxy resin or a phenoldicyclopenta-diene novolac type epoxy resin has been hydrogenated; and a conventionally known epoxy resin which is a liquid state or a solid state at room temperature such as an alicyclic epoxy resin, etc. An epoxy resin(s) other than the above may be used in combination with a certain amount depending on the purposes, if necessary.

In the thermosetting resin layer composed of an epoxy resin, a curing agent of an epoxy resin may be added. Examples of a usable curing agent include a phenol novolac resin, various kinds of amine derivatives, and an acid anhydride; the curing agent may include an acid anhydride group partially ring-opened to form a carboxylic acid. Above all, a phenol novolac resin is desired to ensure the reliability of a semiconductor apparatus to be manufactured. It is particularly preferred that an epoxy resin and a phenol novolac resin are mixed such that the ratio of the epoxy group to the phenolic hydroxyl group becomes 1:0.8 to 1.3.

In addition, imidazole derivatives, phosphine derivatives, amine derivatives, a metal compound such as an organic aluminum compound, etc., may be used as a reaction promoter to promote the reaction of the epoxy resin and the curing agent.

The thermosetting resin layer composed of an epoxy resin may further contain various kinds of additives, if necessary. For example, for the purpose of improving the properties of the resin, various kinds of thermoplastic resins, thermoplastic elastomers, organic synthetic rubbers, stress lowering agents of silicone type or other type, waxes, and additives such as a halogen-trapping agent, etc., may be added properly depending on the purpose.

Since the thermosetting resin layer composed of an epoxy resin becomes a resin layer for encapsulating semiconductor devices, the amount of halogen ions such as chlorine and alkali ions such as sodium, contained therein, is preferably reduced as possible. An exemplary method of reducing these ions includes adding 10 g of a sample in 50 ml of ion exchanged water, leaving the mixture in a sealed oven at 120° C. for 20 hours, and then extracting the resultant sample under heating; it is then desired that all the ions in the sample extracted at 120° C. are 10 ppm or less.

### [Silicone Resin]

The silicone resin used for the thermosetting resin layer of the support-base attached encapsulant may be, but not particularly limited to, a thermosetting silicone resin, a UV curable silicone resin, etc. In particular, the thermosetting resin layer made of a silicone resin desirably contains an addition curable silicone resin composition. The addition curable silicone resin composition particularly preferred is a composition including (A) an organosilicon compound having a nonconjugated double bond (for example, an alkenyl group-containing diorganopolysiloxane), (B) an organohydrogen polysiloxane, and (C) a platinum type catalyst as essential components. These components of (A) to (C) will be described below,

### (A) Component: Organosilicon Compound Having Nonconjugated Double Bond

Examples of the organosilicon compound having a nonconjugated double bond, component (A), include an organopolysiloxane such as a linear diorganopolysiloxane in which both ends of the molecular chain are blocked by triorganosiloxy groups containing aliphatic unsaturated groups expressed as:

R¹¹R¹²R¹³SiO—(R¹⁴R¹⁵SiO)ₐ—(R¹⁶R¹⁷SiO)_{b}—SiR¹¹R¹²R¹³ (1)

wherein R¹¹ represents a monovalent hydrocarbon group containing a nonconjugated double bond, R¹² to R¹⁷ represent identical monovalent hydrocarbon groups or different monovalent hydrocarbon groups, and ‘a’ and ‘b’ are each an integer satisfying 0≦a≦500, 0≦b≦250, and 0≦a+b≦500.

In the above general formula (1), R¹¹ is a monovalent hydrocarbon group containing a nonconjugated double bond, and preferably a monovalent hydrocarbon group containing a nonconjugated double bond with an aliphatic unsaturated bond, as typified by an alkenyl group having 2 to 8 carbon atoms, particularly preferably 2 to 6 carbon atoms.

In the above general formula (1), R¹² to R¹⁷ are identical monovalent hydrocarbon groups or different monovalent hydrocarbon groups; examples thereof include an alkyl group, an alkenyl group, an aryl group, and an aralkyl group each preferably having 1 to 20 carbon atoms, particularly preferably 1 to 10 carbon atoms. Among these, more preferable examples of R¹⁴ to R¹⁷ include a monovalent hydrocarbon group except for an aliphatic unsaturated bond; particularly preferable example thereof include an alkyl group, an aryl group, or aralkyl group, which do not have an aliphatic unsaturated bond unlike an alkenyl group. Among these, preferable examples of R¹⁶ and R¹⁷ include an aromatic monovalent hydrocarbon group; particularly preferable examples thereof include an aryl group having 6 to 12 carbon atoms such as a phenyl group and a tolyl group.

In the above general formula (1), ‘a’ and ‘b’ are each an integer satisfying 0≦a≦500, 0≦b≦250, and 0≦a+b≦500; ‘a’ is preferably 10≦a≦500; ‘b’ is preferably 0≦b≦150; and preferably satisfies 10≦a+b≦500.

The organopolysiloxane expressed by the above general formula (1) can be obtained, for example, by an alkali equilibration reaction between a cyclic diorganopolysiloxane such as cyclic diphenylpolysiloxane, or cyclic methylphenylpolysiloxane and a disiloxane to constitute a terminal group such as diphenyltetravinyidisiloxane, or divinyltetraphenyldisiloxane. In this case, since, in an equilibration reaction by an alkali catalyst (particularly a strong alkali such as KOH), polymerization proceeds with a small amount of the catalyst by an irreversible reaction; thereby a ring-opening polymerization alone proceeds quantitatively and a terminal encapsulating ratio becomes high, a silanol group and a chlorine content are generally not contained.

The organopolysiloxane expressed by the above general formula (1) may be exemplified by the following,

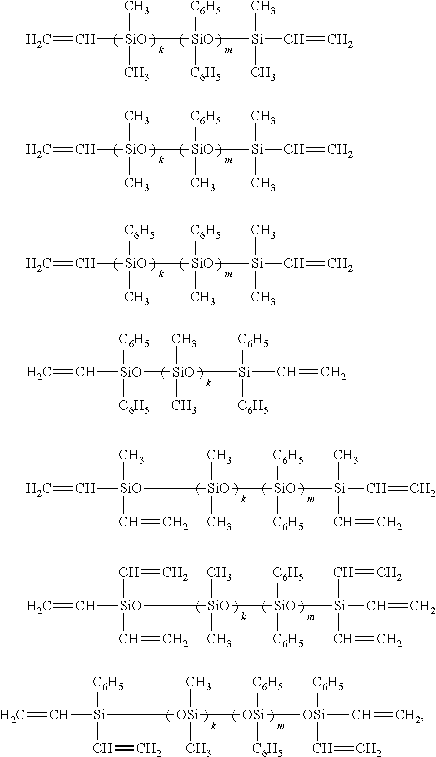

wherein ‘k’ and are each an integer satisfying 0≦k≦500, 0≦m≦250, and 0≦k+m≦500, preferably an integer satisfying 5≦k+m≦250, and 0≦m/(k+m)≦0.5.

The organopolysiloxane having a linear structure expressed by the above general formula (1) may be used as component (A) in combination with an organopolysiloxane hawing a three-dimensional network structure containing a tri-functional siloxane unit or a tetra-functional siloxane unit, etc., if needed. Such a organosilicon compound having a nonconjugated double bond may be used alone or in combination of two or more kinds,

The amount of the group having a nonconjugated double bond (a monovalent hydrocarbon group having a double bond bonded to an. Si atom) in the organosilicon compound having a nonconjugated double bond, component (A), is preferably 0.1 to 20 mol % of the total amount of the monovalent hydrocarbon group (the total amount of a monovalent hydrocarbon group bonded to an Si atom), more preferably 0.2 to 10 mol %, particularly preferably 0.2 to 5 mol %. The reason why these amounts are preferable is that if the amount of the group having a nonconjugated double bond is 0.1 mol % or more, a good cured product can be obtained when it is cured, and if it is 20 mol % or less, the mechanical properties of a cured product become good.

In addition, the organosilicon compound having a nonconjugated double bond, component (A), preferably contains an aromatic monovalent hydrocarbon group (an aromatic monovalent hydrocarbon group bonded to an Si atom); the content of the aromatic monovalent hydrocarbon group is preferably 0 to 95 mol % of the total amount of the monovalent hydrocarbon group (the total amount of a monovalent hydrocarbon group bonded to an Si atom), more preferably 10 to 90 mol %, particularly preferably 20 to 80 mol %. The aromatic monovalent hydrocarbon group provides a merit that a cured product has good mechanical properties and is easy to produce when it is contained in the resin with a suitable amount.

### (B) Component: Organohydrogenpolysiloxane

The component (B) is preferably an organohydrogenpolysiloxane having two or more hydrogen atoms bonded to the silicon atom (SiH group) in one molecule. The organohydrogenpolysiloxane having two or more hydrogen atoms bonded to the silicon atom (SiH group) in one molecule functions as a cross-linking agent and enables the formation of a cured product by addition reaction between the SIB group in component (B) and the group having a nonconjugated double bond such as a vinyl group or an alkenyl group in component (A).

The organohydrogenpolysiloxane, component (B), preferably has an aromatic monovalent hydrocarbon group. If the organohydrogen polysiloxane has an aromatic monovalent hydrocarbon group, then compatibility with the above component (A) can be increased. The organohydrogen polysiloxane may be used alone or in combination of two or more kinds; for example, the organohydrogen polysiloxane having an aromatic hydrocarbon group may be contained as a part of the component (B) or used as the component (B).

Examples of the organohydrogenpolysiloxanes, component (B), include 1,1,3,3-tetramethyldisiloxane, 1,3,5,7-tetramethylcyclotetrasiloxane, tris(dimethylhydrogensiloxy)methylsilane, tris(dimethylhydrogensiloxy)phenylsilane, 1-glysidoxypropyl-1,3,5,7-tetramethylcyclotetrasiloxane, 1,5-glysidoxypropyl-1,3,5,7-tetramethylcyclotetrasiloxane, 1-glysidoxypropyl-5-trimethoxysilylethyl-1,3,5,7-tetramethylcyclotetrasiloxane, methylhydrogenpolysiloxane having both molecular terminals capped with trimethylsiloxy groups, a dimethylsiloxane/methylhydrogensiloxane copolymer having both molecular terminals capped with trimethylsiloxy groups, dimethylpolysiloxane having both molecular terminals capped with dimethylhydrogensiloxy groups, a dimethylsiloxane/methylhydrogensiloxane copolymer having both molecular terminals capped with dimethylhydrogensiloxy groups, a methylhydrogensiloxane/diphenylsiloxane copolymer having both molecular terminals capped with trimethylsiloxy groups, a methylhydrogensiloxane/diphenylsiloxane/dimethylsiloxane copolymer having both molecular terminals capped with trimethylsiloxy groups, a trimethoxysilane polymer, a copolymer of a (CH₃)₂HSiO_{1/2} unit and a SiO_{4/2} unit, and a copolymer of a (CH₃)₂HSiO_{1/2} unit, a SiO_{4/2} unit, and a (C₆H₅) SiO_{3/2} unit, but it is not limited thereto.

In addition, an organohydrogenpolysiloxane obtained by using the unit represented by the following structures may be also used.

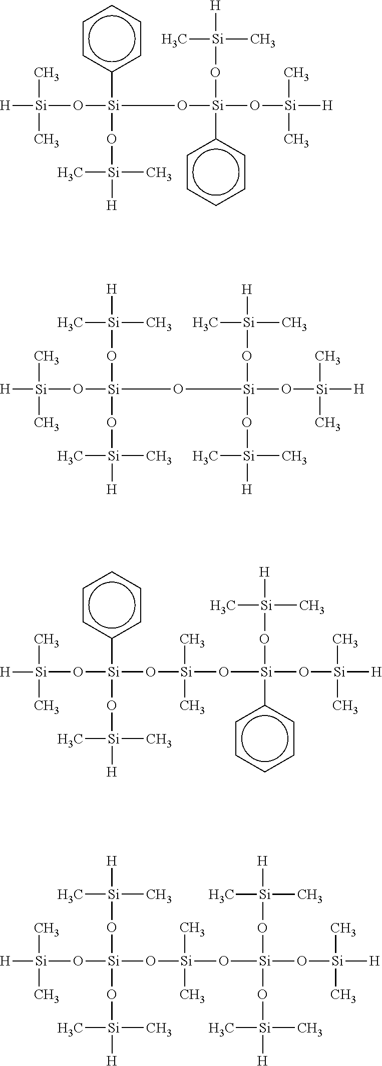

The molecular structure of the organohydrogen polysiloxane, component (B), may be any of a linear, a cyclic, a branched or a three-dimensional network structure, and the number of silicon atoms in one molecule (or a polymerization degree in case of a polymer) is preferably 2 or more, more preferably 3 to 500, particularly preferably 4 to 300 in rough.

The organohydrogen polysiloxane, component (B), is preferably contained such that the number of hydrogen atoms bonded to silicon atoms (SiH group) in component (B) becomes 0.7 to 3.0 per one group having a nonconjugated double bond such as an alkenyl group in component (A).

### (C) Component: Platinum Type Catalyst

Examples of the platinum type catalyst, component (C), include, for example, a chloroplatinic acid, an alcohol-modified chloroplatinic acid, a platinum complex having a chelate structure. These may be used alone or in combination of two or more kinds.

The amount of contained platinum type catalyst, component (C), may be an effective amount for curing, and the so-called catalytic amount; a preferable amount thereof is generally 0.1 to 500 ppm in terms of a mass of the platinum group metal per a total amount of 100 mass parts of the above component (A) and component (B), particularly preferably in the range of 0.5 to 100 ppm.

Since the thermosetting resin layer composed of a silicone resin becomes a resin layer for encapsulating semiconductor devices, the amount of halogen ions such as chlorine and alkali ions such as sodium, contained therein, is preferably reduced as possible. An exemplary method of reducing these ions is the same as in the epoxy resin; it is desired that all the ions in the sample extracted at 120° C. are 10 ppm or less.

### [Epoxy-Silicone Hybrid Resin]

Examples of the epoxy-silicone hybrid resin used in the thermosetting resin layer of the support-base attached encapsulant include, but are not particularly limited to, a hybrid resin using the above epoxy resin and the above silicone resin.

Since the thermosetting resin layer composed of the hybrid resin becomes a resin layer for encapsulating semiconductor devices, the amount of halogen ions such as chlorine and alkali ions such as sodium, contained therein, is preferably reduced as possible. An exemplary method of reducing these ions is the same as in the epoxy resin and silicone resin; it is desired that all the ions in the sample extracted at 120° C. are 10 ppm or less,

### [Cyanate Ester Resin]

The cyanate ester resin used for the thermosetting resin layer of the support-base attached encapsulant may be, but not particularly limited to, a resin composition containing a cyanate ester compound or an oligomer thereof, and a phenol compound and/or a dihydroxynaphthalene compound as curing agent,

### (Cyanate Ester Compound or Oligomer Thereof)

The components used as the cyanate ester compound or the oligomer contained in the cyanate ester resin is expressed by the following general formula (2),

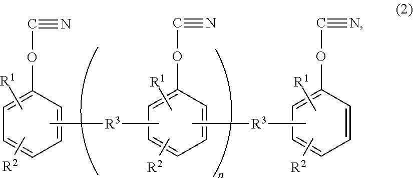

wherein R¹ and R² each represent a hydrogen atom or an alkyl group having 1 to 4 carbon atoms, R³ is represented by any one of:

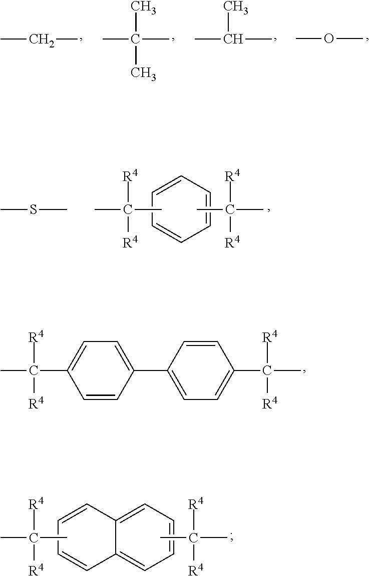

‘n’ is an integer of 0 to 30; R⁴ represents a hydrogen atom or a methyl group.

Here, the cyanate ester compound is a compound having two or more cyanate groups in one molecule, and specifically mentioned a cyanic acid ester of a polycyclic aromatic divalent phenol including, for example, bis(3,5-dimethyl-4-cyanatephenyl)methane, bis(4-cyanatephenyl)methane, bis(3-methyl-4-cyanatephenyl)methane, bis(3-ethyl-4-cyanate-phenyl)methane, bis(4-cyanatephenyl)-1,1-ethane, bis(4-cyanatephenyl)-2,2-propane, di(4-cyanatephenyl) ether, di(4-cyanatephenyl)thio ether; a polycyanic acid ester of a polyvalent phenol including, for example, a phenol novolac type cyanate ester, a cresol novolac type cyanate ester, a phenylaralkyl type cyanate ester, a biphenylaralkyl type cyanate ester, a naphthalenearalkyl type cyanate ester, etc.

The above cyanate ester compound can be obtained by reaction between a phenol and cyanogen chloride under basic conditions. The cyanate ester compound may be selected properly depending on the use from the wide range of materials with characteristics varied due to its structure from a solid state having a softening point of 106° C. to a liquid state at normal temperature.

Among them, a cyanate ester compound having a small cyanate equivalent, i.e., a small amount of molecular weight between functional groups exhibits a slight shrinkage due to curing, enabling a cured product having low thermal expansion and high Tg to be obtained; a cyanate ester compound having a large cyanate equivalent exhibits slightly reduced Tg but increases the flexibility of a triazine cross-linking distance, enabling reduction in elasticity, increase in toughness and reduction in water absorbability to be expected,

Chlorine bonded to or remained in the cyanate ester compound is preferably 50 ppm or less, more preferably 20 ppm or less. It is preferably 50 ppm or less, because there is no possibility that chlorine or chlorine ions, liberated by thermal decomposition when being stored at a high temperature for a long period of time, corrode an oxidized Cu frame, Cu wire or Ag plating, thereby causing exfoliation or electric failure, and reduction in insulation properties of resin can be prevented.

### (Curing Agent)

Typical examples of the curing agent and the curing catalyst of the cyanate ester compound include a metal salt, a metal complex, and a phenolic hydroxyl group or a primary amine each having an active hydrogen; a phenol compound or a dihydroxynaphthalene compound is particularly preferably used.

### Phenol Compound

Examples of the above phenol compound used in the cyanate ester resin include, but are not limited to, a compound expressed by the following general formula (3).

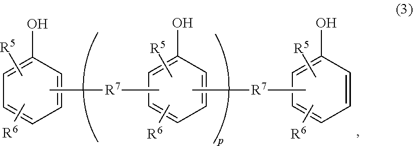

wherein R⁵ and R⁶ each represent a hydrogen atom or an alkyl group having 1 to 4 carbon atoms; R⁷ is represented by any one of:

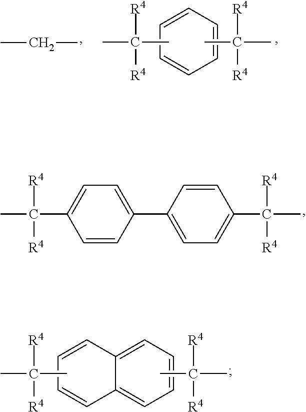

‘p’ is an integer of 0 to 30; R⁴ represents a hydrogen atom or a methyl group.

Here, examples of the phenol compound include a phenol resin, a bisphenol F type resin, a bisphenol A type resin, a phenol novolac resin, a phenolaralkyl type resin, a biphenylaralkyl type resin, and a naphthalenearalkyl type resin each having two phenolic hydroxyl groups in one molecule; one of these may be used alone or in combination of two or more kinds.

Since a phenol compound having a small phenolic hydroxyl equivalent, for example, a hydroxyl equivalent of 120 or less, has high reactivity with a cyanate group, the curing reaction proceeds at a low temperature of 120° C. or lower. In this case, it is preferable to reduce the molar ratio of the hydroxyl group to the cyanate group. This ratio is preferably in the range from 0.05 mol to 0.11 mol per 1 mol of the cyanate group. In this case, a cured product exhibiting a slight shrinkage due to curing, a low thermal expansion, and high Tg can be obtained.

In contrast, since a phenol compound having a large phenolic hydroxyl equivalent, for example, a hydroxyl equivalent of 175 or more, has inhibited reactivity with a cyanate group, a composition having good preservability and good flowability can be obtained. The ratio is preferably in the range from 0.1 mol to 0.4 mol per 1 mol of the cyanate group. In this case, a cured product having low water absorption but a slightly reduced Tg can be obtained. Such a phenol resin may be used in combination of two or more kinds to obtain desired characteristics and curability of the cured product.

The dihydroxynaphthalene compound usable in the cyanate ester resin is expressed by the following general formula (4).

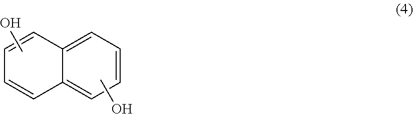

Here, examples of the dihydroxynaphthalene include 1,2-dihydroxynaphthalene, 1,3-dihydroxynaphthalene, 1,4-dihydroxvnaphthalene, 1,5-dihydroxynaphthalene, 1,6-dihydroxynaphthalene, 1,7-dihydroxynaphthalene, 2,6-dihydroxynaphthalene, 2,7-dihydroxynaphthalene.

1,2-dihydroxynaphthalene, 1,3-dihydroxynaphthalene, and 1,6-dihydroxynaphthalene each of which has a melting point of 130° C. have very high reactivity and promote cyclization reaction of the cyanate group with a small amount. 1,5-dihydroxynaphthalene and 2,6-dihydroxynaphthalene each of which has a melting point of 200° C. or higher relatively suppress the reaction.

Use of dihydroxynaphthalene alone makes the molecular weight between functional groups small and the structure rigid, enabling a cured product having a slight shrinkage due to curing and high Tg to be obtained. Use of dihydroxynaphthalene in combination with a phenol compound that has two or more hydroxyl groups in one molecule and hence has a large hydroxyl equivalent enables the curability to be adjusted.

A halogen element and an alkali metal in the above phenol compound and the dihydroxynaphthalene preferably exhibit 10 ppm or less, particularly preferably 5 ppm or less when the sample is extracted at 120° C. under 2 atm.

### [Inorganic Filler]

The thermosetting resin layer of the support-base attached encapsulant may contain an inorganic filer. Known inorganic fillers of various kinds can be used as the inorganic filler; specific examples thereof include fumed silica (aerosol silica), precipitated silica, fused silica, crystalline silica, alumina, boron nitride, aluminum nitride, silicon nitride, magnesia, magnesium silicate, and aluminum; fused silica with a perfect circle shape is preferable because of low viscosity; spherical silica produced by the sol-gel process or the deflagration process is also preferably used. These inorganic fillers may be subjected to surface treatment with a silane coupling agent etc., but used without surface treatment.

The amount of the inorganic filler is preferably 50 to 90 mass % of the total resin component of the thermosetting resin layer of the support-base attached encapsulant, particularly preferably 60 to 85 mass %. When the amount is 50 mass % or more, reduction in strength and reliability of wet-resistance can be inhibited; when the amount is 90 mass % or less, reduction in invasiveness of the underfill due to increase in viscosity can be inhibited.

### EXAMPLES

The present invention will be described below with reference to examples and comparative examples, but the present invention is not restricted to these examples.

### Example 1

### [Semiconductor-Device Mounting Substrate]

A BT (bismaleimide triazine) resin substrate having a thickness of 100 μm and a size of 240 mm×240 mm and a linear expansion coefficient of 10 ppm/° C. was prepared as an organic resin substrate. This substrate had a Cu wiring so as to be capable of mounting 168 chips having a size of 7.3 mm×7.3 mm (having a full area pad with a pad diameter of 100 μm and a pad pitch of 300 μm; a peripheral lead with a lead width of 20 μm and a lead pitch of 80 μm). On the Cu-wiring forming surface of the substrate was flip-chip bonded 168 chips having a size of 7.3 mm×7.3 mm and a thickness of 100 μm that were arranged such that a 30-μm-height Cu pillar and a 15-μm SnAg could be connected with the wiring The height of a gap defined between the chips and the substrate after the connection was 48 μm.

### [Support Base]

A BT resin substrate having a thickness of 50 μm and a size of 230 mm×230 mm and a linear expansion coefficient of 6 ppm/° C. was prepared.

[Resin. Component of Thermosetting Resin Layer]

60 parts by mass of a cresol novolac type epoxy resin, 30 parts by mass of a phenol novolac resin, 350 parts by mass of spherical silica having an average particle diameter of 0.6 μm in which 0.08 mass % of particles with a particle diameter of 10 μm or more is contained, 0.8 part by mass of a catalyst TPP (triphenylphosphine), and 0.5 part by mass of a silane coupling agent KBM403 (γ-glycidoxypropyltrimethoxysilane, made by Shin-Etsu Chemical Co., Ltd.) were sufficiently mixed by a high-speed mixing apparatus. The resultant was heated and kneaded with a continuously kneading apparatus to form a sheet with a thickness of about 150 μm and the sheet was then cooled.

### [Manufacture of Support-Base Attached Encapsulant]

The sheet made of an epoxy resin composition was stacked on a surface of the support base. A PET film (a peeling film) subjected to a fluorine resin treatment was stacked on the stacked epoxy resin composition. The resultant was crimped at 50° C. to manufacture a support-base attached encapsulant.

### [Encapsulation of Device Mounting Substrate]

The device mounting substrate was encapsulated with the manufactured support-base attached encapsulant by using a vacuum laminating′ apparatus (manufactured by Nichigo-Morton Co., Ltd.)

As shown in FIG. 3, the support-base attached encapsulant was placed on the bottom 45 of a lower part 44 of the frame mechanism such that the thermosetting resin layer faced upward. The device mounting substrate was held at the upper part 43 of the frame mechanism with the holding unit 41 such that the device mounting surface faced downward. As shown in FIG. 2, the upper part 43 of the frame mechanism was then put on the lower part 44. At this time, the space 42 was interposed therebetween such that the support-base attached encapsulant did not contact the device mounting substrate.

The temperature of the upper and lower plates was previously set at 150° C. The frame mechanism 31 was then placed on the lower plate 36 of the vacuum laminating apparatus 30. The lower plate was raised to come into close contact with the upper plate so that the vacuum chamber was defined. After the pressure of the vacuum chamber was reduced to 502a, the atmosphere between the upper plate and the diaphragm rubber was opened and compressed air with a pressure of 0.5 Mpa was applied for pressing for 5 minutes. A resin layer with a thickness of 225 μm was formed in a first cavity and an excess of resin was discharged into a second cavity.

The encapsulated device mounting substrate was taken out and post-cured at 180° C. for four hours to cure the thermosetting resin layer. The accuracy of the encapsulated device mounting substrate was checked by cross-sectional observation. The resin extending sag shape did not occur at the outer circumferential portion of the thermosetting resin layer. The total thickness after the encapsulation was 325 μm±5 μm.

The substrate was attached to a dicing tape to cut by dicing into individual pieces, so that a semiconductor apparatus with a size of 16 mm×16 mm was manufactured. The investigation of this semiconductor apparatus by an ultrasonic testing apparatus and observation of the cross-section of a cut semiconductor device of the semiconductor apparatus revealed that there was no void in the semiconductor apparatus and the invasiveness was good.

### <Warp of Package>

The difference in height of the semiconductor apparatus was measured in a diagonal direction with a laser coordinate measuring machine to define the difference as the mount of warp (mm).

### <Invasiveness of Underfill>

The semiconductor apparatus was investigated by an ultrasonic testing apparatus and observation of the cross-section of a cut semiconductor device of the semiconductor apparatus to check voids and a portion in which resin was not filled (a non-filling portion). When there was no void and no non-filling portion, the invasiveness was determined as good.

### <Wet-Resistant Property>

The semiconductor apparatus is left in a thermo-hygrostat at 85° C. and 60% RH for 168 hours to absorb moisture. An infrared reflow process based on JEDEC Level 2 was then carried out at 260° C. The occurrence of an internal crack and peeling were observed by an ultrasonic testing apparatus and observation of the cross-section of a cut semiconductor device. The number of packages containing a crack or peeling was counted among a total of 20 packages.

### Example 2

A device mounting substrate and a support-base attached encapsulant were prepared and encapsulated with a vacuum laminating apparatus (manufactured by Nichigo-Morton Co., Ltd.) as in example 1. The encapsulation, curing, and cutting were performed in the same conditions as in example 1 except that the pressure of the vacuum chamber was reduced to 800 Pa.

### Comparative Example 1

A device mounting substrate and a support-base attached encapsulant were prepared and encapsulated with a vacuum laminating apparatus (manufactured by Nichigo-Morton Co., Ltd.) as in example 1, except that the frame mechanism of the present invention was not used and the device mounting substrate and the support-base attached encapsulant were placed on the lower plate such that the thermosetting resin layer of the support-base attached encapsulant was placed on the device mounting surface. Other conditions to perform the encapsulation and curing were the same as in example 1. The cross-sectional observation of the accuracy of the encapsulated device mounting substrate revealed that the resin extending sag shape occurred at the outer circumferential portion of the thermosetting resin layer. The total thickness after the encapsulation was 325 μm at the center and 300 μm at a peripheral portion. As in example 1, the investigation of this semiconductor apparatus by an ultrasonic testing apparatus and observation of the cross-section of a cut semiconductor device of the semiconductor apparatus revealed that there was no void in the semiconductor apparatus and the invasiveness was good.

### Comparative Example 2

The temperature of molds of a compression molding apparatus was set at 150° C. The device mounting substrate was attached by suction to an upper mold. Likewise, the support-base attached encapsulant on which the above thermosetting epoxy resin had been formed was attached by suction to a lower mold.

The periphery of the molds was sealed. After air in the interior was sucked to create a vacuum of 5 kPa, the upper and lower molds were closed. The target thickness after molding was 225 μm. A pressure of 20 kg/cm² was then applied to perform compression molding for a molding time of 5 minutes. The encapsulated device mounting substrate was then taken out and post cured at 180° C. for four hours to cure the thermosetting resin. The total thickness after the encapsulation was about 325 μm±5 μm.

The substrate was attached to a dicing tape and cut by dicing into individual pieces, so that a semiconductor apparatus with a size of 16 mm×16 mm was manufactured. The investigation of this semiconductor apparatus by an ultrasonic testing apparatus and observation of the cross-section of a cut semiconductor device of the semiconductor apparatus revealed that a portion in which resin was not filled was observed in a gap between the substrate and the semiconductor device mounted through flip chip bonding at the center of the device.

The result of examples 1 and 2 and comparative example 2 is given in Table 1. As shown in Table 1, examples 1 and 2 demonstrated that the invasiveness of underfill was good and there was no package containing a crack or peeling. In contrast, comparative example 2 demonstrated that a non-filling portion was created in the underfill and there were many packages containing a crack or peeling. In addition, the warp of the packages in examples 1 and 2 was able to be suppressed to or below the same level as that in comparative example 2.

TABLE 1

| | EXAMPLE | EXAMPLE | COMPARATIVE |
|---|---|---|---|
| | 1 | 2 | EXAMPLE 2 |
| PACKAGE WARP | 45 | 50 | 60 |
| (μm) | | | |
| UNDERFILL | GOOD | GOOD | NON-FILLING |
| INVASIVENESS | | | PORTION |
| | | | EXISTED |
| WET-RESISTANCE | 0/20 | 0/20 | 18/20 |

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A method for manufacturing a semiconductor apparatus, comprising:
a preparation step of preparing a support-base attached encapsulant including a thermosetting resin layer stacked as an encapsulant on a support base;
a coating step of coating a semiconductor-device mounting surface of a substrate on which semiconductor devices are mounted, or a semiconductor-device forming surface of a wafer on which semiconductor devices are formed with the thermosetting resin layer of the support-base attached encapsulant;
an encapsulating step of heating and curing the thermosetting resin layer to collectively encapsulate the semiconductor-device mounting surface of the substrate or the semiconductor-device forming surface of the wafer;
a cutting step of cutting the encapsulated substrate or wafer by dicing; wherein
the coating step includes surrounding at least a side face of the support-base attached encapsulant by a frame mechanism, holding the substrate or the wafer with the substrate or the wafer facing and spaced apart from the thermosetting resin layer of the support-base attached encapsulant, and vacuum laminating the support-base attached encapsulant surrounded by the frame mechanism together with the substrate or the wafer.

2. The method for manufacturing a semiconductor apparatus according to claim 1, wherein the preparation step includes stacking the thermosetting resin layer as an encapsulant on the support base in excess of an amount necessary for manufacturing the semiconductor apparatus, and the coating step is performed while discharging an excess of the thermosetting resin layer to an exterior.

3. The method for manufacturing a semiconductor apparatus according to claim 1, wherein the coating step includes engaging a fastener with a peripheral portion of the substrate or the wafer to hold the substrate or the wafer from above with the semiconductor-device mounting surface or the semiconductor-device forming surface facing downward.

4. The method for manufacturing a semiconductor apparatus according to claim 2, wherein the coating step includes engaging a fastener with a peripheral portion of the substrate or the wafer to hold the substrate or the wafer from above with the semiconductor-device mounting surface or the semiconductor-device forming surface facing downward.

5. The method for manufacturing a semiconductor apparatus according to claim 1, wherein the vacuum lamination in the coating step is performed under a reduced pressure of 10 Pa to 1 kPa.

6. The method for manufacturing a semiconductor apparatus according to claim 2, wherein the vacuum lamination in the coating step is performed under a reduced pressure of 10 Pa to 1 kPa.

7. The method for manufacturing a semiconductor apparatus according to claim 3, wherein the vacuum lamination in the coating step is performed under a reduced pressure of 10 Pa to 1 kPa.

8. The method for manufacturing a semiconductor apparatus according to claim 4, wherein the vacuum lamination in the coating step is performed under a reduced pressure of 10 Pa to 1 kPa.

9. The method for manufacturing a semiconductor apparatus according to claim 1, wherein a substrate having an area of 200 mm×200 mm or more is used as the substrate on which semiconductor devices are mounted, and a wafer having an area of a diameter of 200 mm or more is used as the wafer on which semiconductor devices are formed.

10. The method for manufacturing a semiconductor apparatus according to claim 8, wherein a substrate having an area of 200 mm×200 mm or more is used as the substrate on which semiconductor devices are mounted, and a wafer having an area of a diameter of 200 mm or more is used as the wafer on which semiconductor devices are formed.

11. The method for manufacturing a semiconductor apparatus according to claim 1, wherein a vacuum laminating apparatus capable of heating the substrate or the wafer under vacuum is used to perform the vacuum lamination in the coating step and subsequently′ the encapsulating step.

12. The method for manufacturing a semiconductor apparatus according to claim 10, wherein a vacuum laminating apparatus capable of heating the substrate or the wafer under vacuum is used to perform the vacuum lamination in the coating step and subsequently the encapsulating step.
